(19) United States
(12) Patent Application Publication
(10) Pub. No.: US 2009/0039776 A1
(43) Pub. Date: Feb. 12, 2009

(54) ORGANOMETALLIC COMPLEX AND ORGANIC LIGHT-EMITTING ELEMENT USING SAME

(75) Inventors: Naoki Yamada, Inagi-shi (JP); Tomona Yamaguchi, Tokyo (JP); Jun Kamatani, Tokyo (JP); Minako Nakasu, Tokyo (JP); Ryota Ooishi, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/179,899

(22) Filed: Jul. 25, 2008

(30) Foreign Application Priority Data
Aug. 9, 2007 (JP) 2007-208038

(51) Int. Cl. H01L 51/52; C07F 15/00

(52) U.S. Cl. 313/504; 544/225

(57) ABSTRACT

An organometallic complex and an organic light-emitting element containing the complex which has a very high efficiency, a high luminance, and durability. The organic light-emitting element has an anode, a cathode, and a layer including an organic compound sandwiched between the anode and cathode. The layer containing the organic compound includes at least one organometallic complex represented by General Formula [I] below.

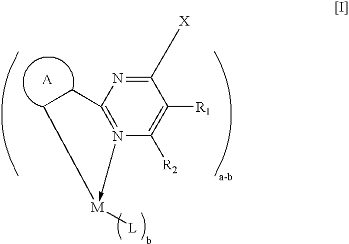

### BACKGROUND OF THE INVENTION

1. Field of the Invention

The present invention relates to an organometallic complex and an organic light-emitting element using same.

2. Description of the Related Art

An organic light-emitting element is an element in which a thin film containing a fluorescent organic compound or phosphorescent organic compound is sandwiched between an anode and a cathode. By injecting holes (vacancies) and electrons from respective electrodes, the fluorescent compound or phosphorescent compound generates excitons, and the organic light-emitting element emits light when the excitons return to the ground state.

Significant progress has recently been achieved in the field of organic light-emitting elements, thereby making it possible to obtain organic light-emitting elements of reduced thickness and weight and featuring a high luminance at a low applied voltage, a large variety of emission wavelengths and a high-speed responsiveness. Accordingly, such elements can be applied in a wide range of applications.

However, a light output of even higher luminance and a higher conversion efficiency are presently required. Furthermore, a large number of problems are still associated with durability, such as change in performance with time during long-term use and deterioration caused by oxygen-containing atmosphere gas or moisture.

Further, when applications to full-color displays are considered, blue, green, and red emitted light of good color purity is required. However, this problem is also yet to be resolved.

Using an organometallic complex having a phenylpyrimidine ligand as a constituent material of an organic light-emitting element has been suggested as a method for resolving the above-described problems. Examples of organometallic complexes having a phenylpyrimidine ligand and organic light-emitting elements comprising such organometallic complexes are described in International Patent Application No. WO02/02714 and Japanese Patent Laid-open No. 2005-220136. However, organic light-emitting elements disclosed in these documents have a low emission efficiency and insufficient durability.

### SUMMARY OF THE INVENTION

The present invention provides a novel organometallic complex. Further, the present invention provides an organic light-emitting element that has a very high efficiency, a high luminance, and extended durability. It is yet another object of the present invention to provide an organic light-emitting element that is easy to manufacture and that can be produced at a comparatively low cost.

The organometallic complex in accordance with the present invention is represented by the General Formula [I] below:

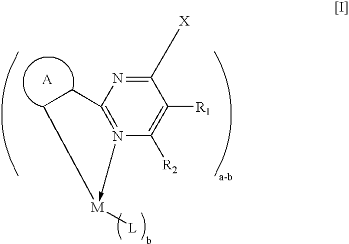

In Formula [I], M is iridium, platinum, or gold. A is a substituted or unsubstituted aryl group. X is a substituted or unsubstituted alkyl group, a substituted or unsubstituted aralkyl group, a substituted or unsubstituted alkoxy group, a substituted or unsubstituted aryloxy group, a substituted or unsubstituted aryl group, a substituted or unsubstituted heterocyclic group, or a cyano group. R₁ and R₂, are the same or different, are each a hydrogen atom, a substituted or unsubstituted alkyl group, a substituted or unsubstituted aralkyl group, a substituted or unsubstituted alkoxy group, a substituted or unsubstituted aryloxy group, a substituted or unsubstituted aryl group, a substituted or unsubstituted heterocyclic group, an amino group, a cyano group, or a halogen atom. Further, R₁ and R₂ may be bonded to each other, forming a ring. L is an optionally substituted monoanionic bidentate ligand a is integer of 1 to 3, b is integer of 0 to 2. When b is 2, each L may be the same or different.

In accordance with the present invention, a novel organometallic complex can be provided. Further, in accordance with the present invention, an organic light-emitting element that has a very high efficiency, a high luminance, and durability can be provided.

Further features of the present invention will become apparent from the following description of exemplary embodiments (with reference to the attached drawings).

### BRIEF DESCRIPTION OF THE DRAWINGS

FIG. 1 is a cross-sectional view illustrating a first embodiment of the organic light-emitting element in accordance with the present invention.

FIG. 2 is a cross-sectional view illustrating a second embodiment of the organic light-emitting element in accordance with the present invention.

FIG. 3 is a cross-sectional view illustrating a third embodiment of the organic light-emitting element in accordance with the present invention.

FIG. 4 is a cross-sectional view illustrating a fourth embodiment of the organic light-emitting element in accordance with the present invention.

FIG. 5 is a cross-sectional view illustrating a fifth embodiment of the organic light-emitting element in accordance with the present invention.

FIG. 6 shows a ¹H-NMR chart of Example Compound No. 3 synthesized in Example 2.

### DESCRIPTION OF THE EMBODIMENTS

The organometallic complex in accordance with the present invention will be described below. The organometallic complex in accordance with the present invention is represented by the General Formula [I] below.

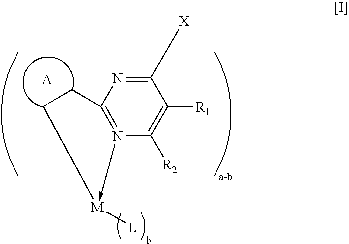

In Formula [I], M is iridium, platinum, or gold. Preferably, M is iridium or platinum.

In Formula [I], A is a substituted or unsubstituted aryl group.

Examples of an aryl group represented by A include phenyl group, naphthyl group, pentalenyl group, indenyl group, azulenyl group, anthryl group, pyrenyl group, indacenyl group, acenaphthenyl group, phenanthryl group, phenalenyl group, fluoranthenyl group, acephenanthryl group, aceanthryl group, triphenylenyl group, chrysenyl group, naphthacenyl group, perylenyl group, pentacenyl group, biphenyl group, terphenyl group, and fluorenyl group. The preferred aryl group is a phenyl group.

Examples of substituents for the aryl group represented by A include alkyl groups such as methyl group, ethyl group, and propyl group; aralkyl groups such as benzyl group and phenethyl group; alkoxyl groups such as methoxyl group, ethoxyl group, and propoxyl group; aryl groups such as phenyl group and biphenyl group; heterocyclic groups such as thienyl group, pyrrolyl group, and pyridyl group; aryloxyl groups such as phenoxyl group; amino groups such as dimethylamino group, diethylamino group, dibenzylamino group, diphenylamino group, ditolylamino group, and dianisolylamino group; and cyano group.

In Formula [I], X is a substituted or unsubstituted alkyl group, a substituted or unsubstituted aralkyl group, a substituted or unsubstituted alkoxy group, a substituted or unsubstituted aryl group, a substituted or unsubstituted heterocyclic group, a substituted or unsubstituted aryloxy group, or a cyano group. The preferred X is a substituted or unsubstituted alkyl group.

Examples of alkyl group represented by X include methyl group, ethyl group, normal propyl group, isopropyl group, normal butyl group, tertiary butyl group, secondary butyl group, octyl group, 1-adamantyl group, and 2-adamantyl group.

Examples of aralkyl group represented by X include benzyl group and phenethyl group.

Examples of alkoxy group represented by X include methoxy group, ethoxy group, and propoxy group.

Examples of aryl group represented by X include phenyl group, naphthyl group, pentalenyl group, indenyl group, azulenyl group, anthryl group, pyrenyl group, indacenyl group, acenaphthenyl group, phenanthryl group, phenalenyl group, fluoranthenyl group, acephenanthryl group, aceanthryl group, triphenylenyl group, chrysenyl group, naphthacenyl group, perylenyl group, pentacenyl group, biphenyl group, terphenyl group, and fluorenyl group.

Examples of heterocyclic group represented by X include thienyl group, pyrrolyl group, pyridyl group, oxazolyl group, oxadiazolyl group, thiazolyl group, thiadiazolyl group, terthienyl group, carbazolyl group, acridinyl group, and phenanthrolyl group.

Examples of aryloxy group represented by X include phenoxy group.

Examples of substituents for the aforementioned alkyl group, aralkyl group, alkoxy group, aryl group, heterocyclic group, and aryloxy group represented by X include alkyl groups such as methyl group, ethyl group, and propyl group; aralkyl groups such as benzyl group and phenethyl group; alkoxy groups such as methoxy group, ethoxy group, and propoxy group; aryl groups such as phenyl group and biphenyl group; heterocyclic groups such as thienyl group, pyrrolyl group, and pyridyl group; aryloxy groups such as phenoxy group; amino groups such as dimethylamino group, diethylamino group, dibenzylamino group, diphenylamino group, ditolylamino group, and dianisolylamino group; and cyano group.

In Formula [I], R₁ and R₂, which may be the same or different, are each a hydrogen atom, a substituted or unsubstituted alkyl group, a substituted or unsubstituted aralkyl group, a substituted or unsubstituted alkoxy group, a substituted or unsubstituted aryl group, a substituted or unsubstituted heterocyclic group, a substituted or unsubstituted aryloxy group, an amino group, a cyano group, or a halogen atom.

Examples of alkyl group represented by R₁ and R₂ include methyl group, ethyl group, normal propyl group, isopropyl group, normal butyl group, tertiary butyl group, secondary butyl group, octyl group, 1-adamantyl group, and 2-adamantyl group.

Examples of aralkyl group represented by R₁ and R₂ include benzyl group and phenethyl group.

Examples of alkoxy group represented by R₁ and R₂ include methoxy group, ethoxy group, and propoxy group.

Examples of aryl group represented by R₁ and R₂ include phenyl group, naphthyl group, pentalenyl group, indenyl group, azulenyl group, anthryl group, pyrenyl group, indacenyl group, acenaphthenyl group, phenanthryl group, phenalenyl group, fluoranthenyl group, acephenanthryl group, aceanthryl group, triphenylenyl group, chrysenyl group, naphthacenyl group, perylenyl group, pentacenyl group, biphenyl group, terphenyl group, and fluorenyl group.

Examples of heterocyclic group represented by R₁ and R₂ include thienyl group, pyrrolyl group, pyridyl group, oxazolyl group, oxadiazolyl group, thiazolyl group, thiadiazolyl group, terthienyl group, carbazolyl group, acridinyl group, and phenanthrolyl group.

Examples of aryloxy group represented by R₁ and R₂ include phenoxy group.

Examples of amino group represented by R₁ and R₂ include dimethylamino group, diethylamino group, dibenzylamino group, diphenylamino group, ditolylamino group, and dianisolylamino group.

Examples of halogen atom represented by R₁ and R₂ include bromine atom, chlorine atom, and iodine atom.

Examples of substituents that may be contained in the aforementioned alkyl group, aralkyl group, alkoxy group, aryl group, heterocyclic group, and aryloxy group include alkyl groups such as methyl group, ethyl group, and propyl group; aralkyl groups such as benzyl group and phenethyl group; alkoxy groups such as methoxy group, ethoxy group, and propoxy group; aryl groups such as phenyl group and biphenyl group; heterocyclic groups such as thienyl group, pyrrolyl group, and pyridyl group; aryloxy groups such as phenoxy group; amino groups such as dimethylamino group, diethylamino group, dibenzylamino group, diphenylamino group, ditolylamino group, and dianisolylamino group; and cyano group.

R₁ and R₂ may be the same or different. Further, R₁ and R₂ may be bonded to each other, forming a ring.

In Formula [I], L stands for an optionally substituted monoanionic bidentate ligand.

Specific examples of the optionally substituted monoanionic bidentate ligand represented by L include acetylacetonate, picolinic acid, salicylanilide, quinolinecarboxylic acid esters, 8-hydroxyquinolinate, L-proline, 1,5-dimethyl-3-pyrazole carboxylic acid esters, tetramethylheptane dionate, 1-(2-hydroxyphenyl)pyrazolate, phenylpyrazole, phenylpyridine, phenylisoquinoline, methoxyphenylisoquinoline, dihydroazaphenanthrene, tetramethyldihydroazaphenanthrene, and benzothienylisoquinoline.

In Formula [I], a is an integer of 1 to 3.

In Formula [I], b is an integer of 0 to 2. Preferably, b is 0. When b is 2, each L is the same or different.

In the organometallic complex in accordance with the present invention, a phenylpyrimidine skeleton serves as the main skeleton. Further, in the organic light-emitting element in accordance with the present invention, a nitrogen atom, from among the two nitrogen atoms contained in the pyrimidine skeleton, which does not form a coordinate bond with the metal (also known as the coordinate-free nitrogen) is protected by a substituent, X, with a large steric hindrance that is bonded to the adjacent carbon atom.

Because the coordinate-free nitrogen is protected, it is possible to inhibit both the oxidation of the coordinate-free nitrogen by oxygen or the like and the formation of a coordinate bond of the coordinate-free nitrogen and metal. Further, the target or desired organometallic complex can be obtained in a good yield and the formation of undesired isomers can be inhibited. In addition, thermal stability of the complex itself is increased and service life of an organic light-emitting element using the complex as a constituent material is increased.

Preferred examples of the group X providing the coordinate-free nitrogen with large steric hindrance include substituted or unsubstituted alkyl groups, substituted or unsubstituted aralkyl groups, substituted or unsubstituted alkoxy groups, substituted or unsubstituted aryl groups, substituted or unsubstituted heterocyclic groups, and substituted or unsubstituted aryloxy groups. Particularly preferred among them are substituted or unsubstituted alkyl groups.

Further, substituent X with a large steric hindrance is preferably larger than R₂ in Formula [I], which is a substituent in the pyrimidine skeleton. As a result, the effect of inhibiting the generation of isomers is augmented. In contrast, for example, a halogen atom or a substituent containing a halogen atom that is disclosed in International Patent Application No. WO02/02714 is not included in the present substituents with a large steric hindrance. This is because the complex itself becomes unstable and the transition process of phosphorescent light emission becomes π-π* transition, whereby the light emission efficiency of the element employed as a constituent material of an organic light-emitting element decreases.

Because the organometallic complex in accordance with the present invention comprises a ligand having a pyrimidine skeleton, it also has an electron injection ability. Therefore, when such a complex is used as a constituent material of an organic light-emitting element, the drive voltage of the element can be decreased. Further, by introducing a substituent into the pyrimidine skeleton in the ligand having the pyrimidine skeleton, it is possible to adjust the electron injecting ability of the complex itself. As a result, it is possible to implement a molecular design that accounts for a balance of carrier injection of holes and electrons. On the other hand, introducing a substituent into a pyrimidine group enables the molecular design of light-emitting materials of blue, green, and red color.

In the organometallic complex in accordance with the present invention, A in Formula [I] is an aryl group. On the other hand, when the A is a heterocyclic group disclosed in Japanese Patent Application Laid-open No. 2005-220136, the complex itself becomes unstable.

Specific examples of the organometallic complex in accordance with the present invention will be described below. As shown hereinbelow, the organometallic complex in accordance with the present invention comprises three ligands L₁, L₂, L₃ and a central metal (for example, the below-described Ir).

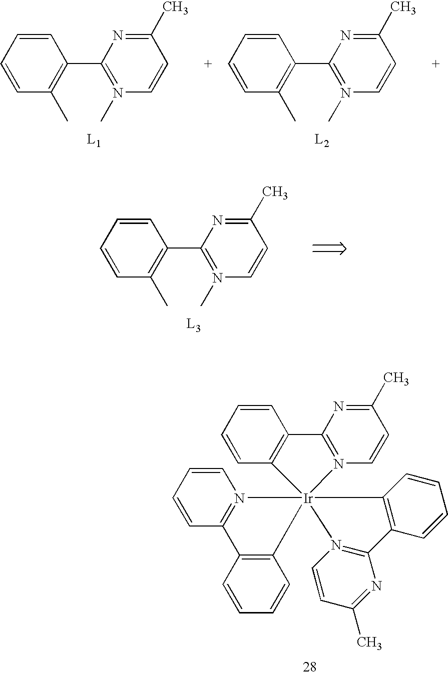

Specific examples of the L₁, L₂, L₃ and central metal are individually presented in tables below. However, the present invention is not limited to these examples.

TABLE 1

| | CENTRAL | | | |
|---|---|---|---|---|
| No. | METAL | L₁ | L₂ | L₃ |
| 1 | Ir | 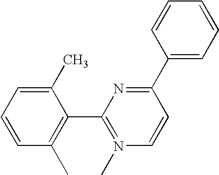 | 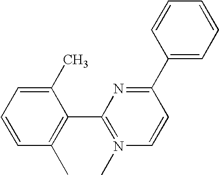 | 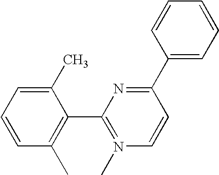 |
| 2 | Ir | 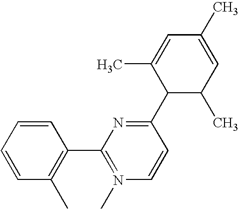 | 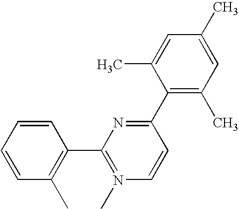 | 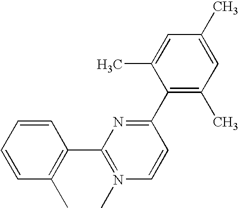 |
| 3 | Ir | 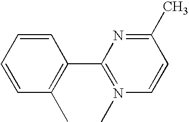 | 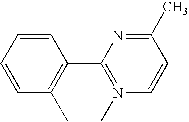 | 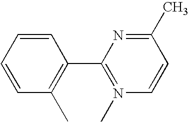 |
| 4 | Ir | 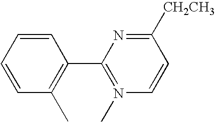 | 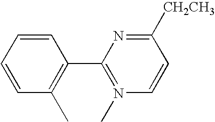 | 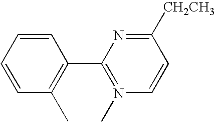 |
| 5 | Ir | 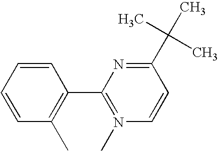 | 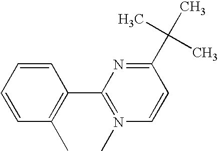 | 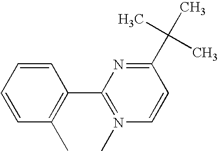 |
| 6 | Ir | 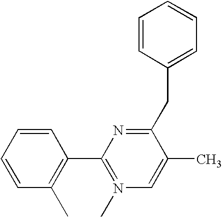 | 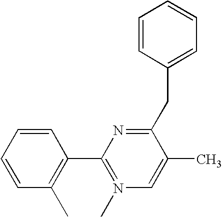 | 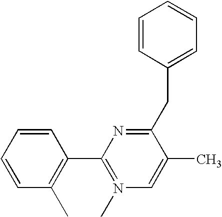 |
| 7 | Ir | 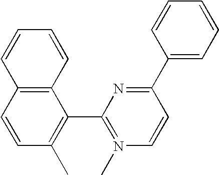 | 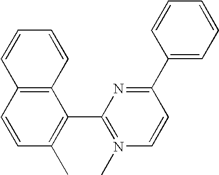 | 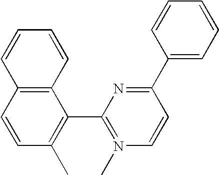 |

TABLE 2

| | CENTRAL | | | |
|---|---|---|---|---|
| No. | METAL | L₁ | L₂ | L₃ |
| 8 | Ir | 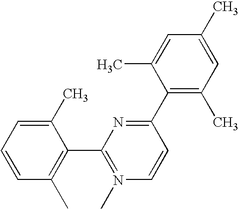 | 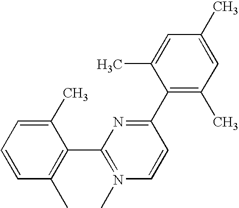 | 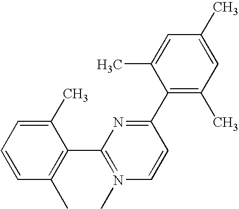 |
| 9 | Ir | 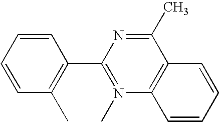 | 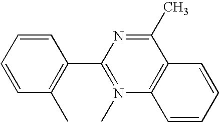 | 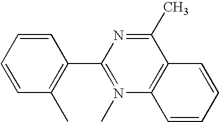 |
| 10 | Ir | 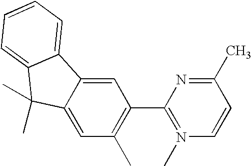 | 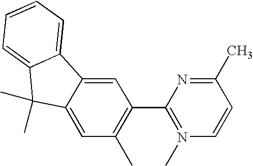 | 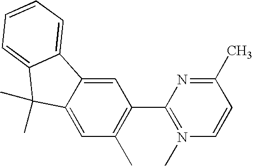 |
| 11 | Ir | 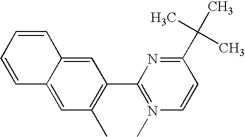 | 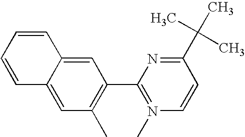 | 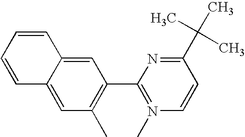 |
| 12 | Ir | 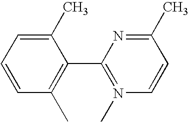 | 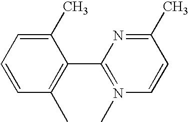 | 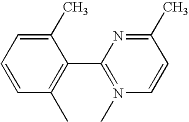 |
| 13 | Ir | 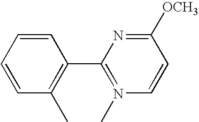 | 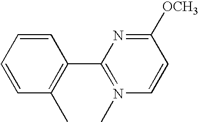 | 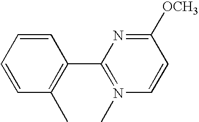 |
| 14 | Ir | 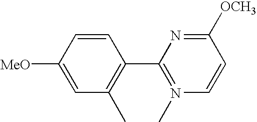 | 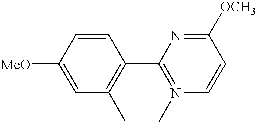 | 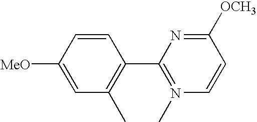 |
| 15 | Ir | 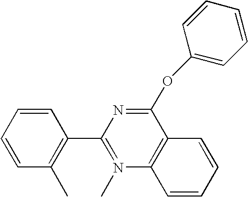 | 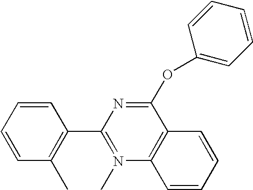 | 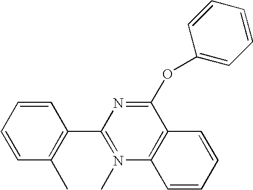 |

TABLE 3

| | CENTRAL | | | |
|---|---|---|---|---|
| No. | METAL | L₁ | L₂ | L₃ |
| 16 | Ir | 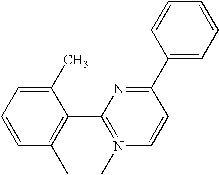 | 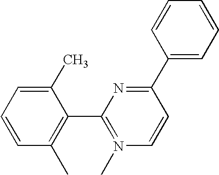 | 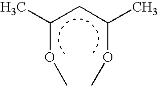 |
| 17 | Ir | 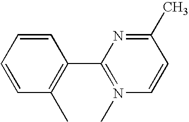 | 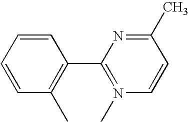 | 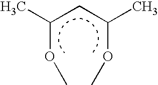 |
| 18 | Ir | 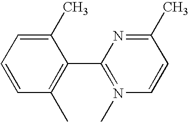 | 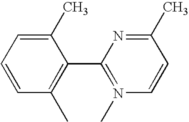 | 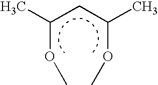 |
| 19 | Ir | 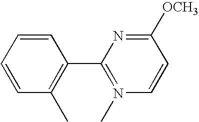 | 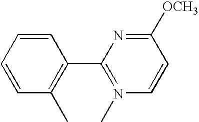 | 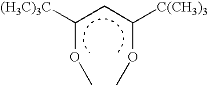 |
| 20 | Ir | 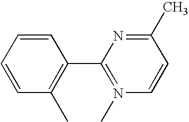 | 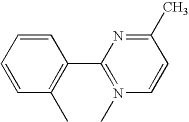 | 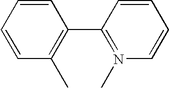 |
| 21 | Ir | 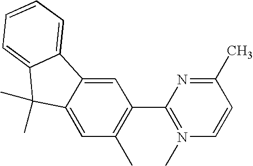 | 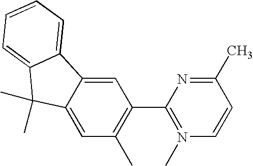 | 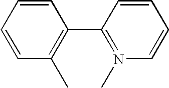 |
| 22 | Ir | 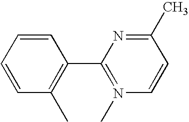 | 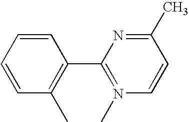 | 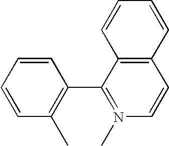 |
| 23 | Ir | 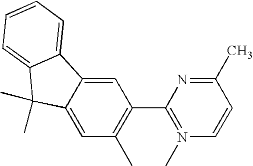 | 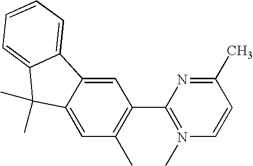 | 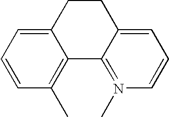 |

TABLE 4

| | CENTRAL | | | |
|---|---|---|---|---|
| No. | METAL | L₁ | L₂ | L₃ |
| 24 | Ir | 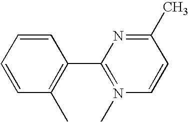 | 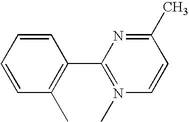 | 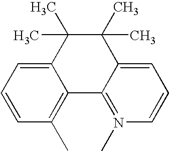 |
| 25 | Ir | 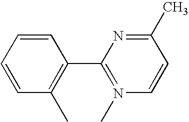 | 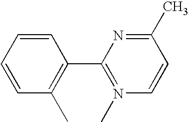 | 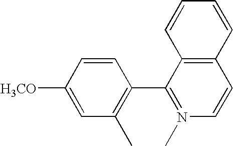 |
| 26 | Ir | 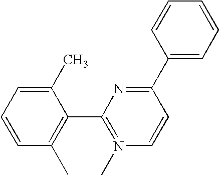 | 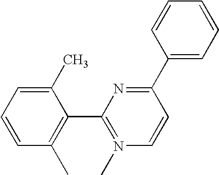 | 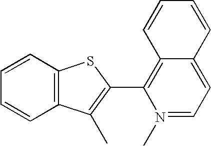 |
| 27 | Ir | 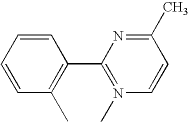 | 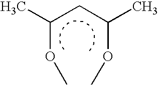 | 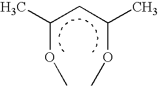 |
| 28 | Ir | 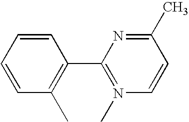 | 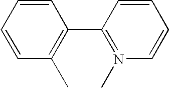 | 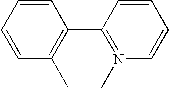 |
| 29 | Ir | 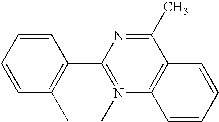 | 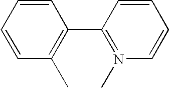 | 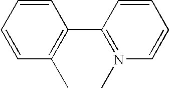 |
| 30 | Ir | 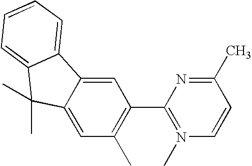 | 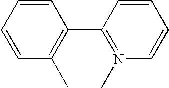 | 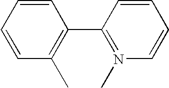 |

TABLE 5

| | CENTRAL | | | |
|---|---|---|---|---|
| No. | METAL | L₁ | L₂ | L₃ |
| 31 | Ir | 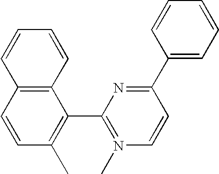 | 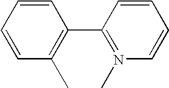 | 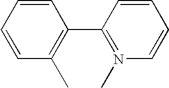 |
| 32 | Ir | 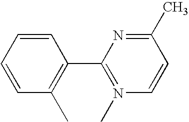 | 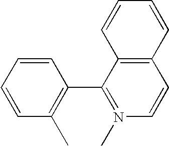 | 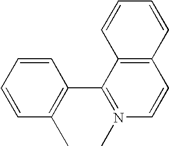 |
| 33 | Ir | 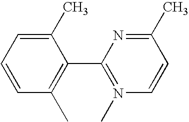 | 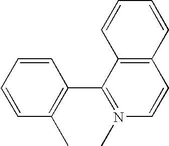 | 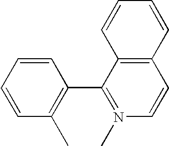 |
| 34 | Ir | 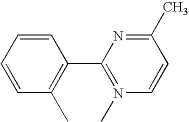 | 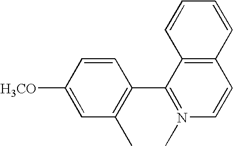 | 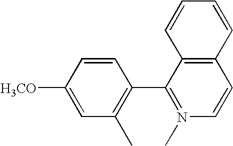 |
| 35 | Ir | 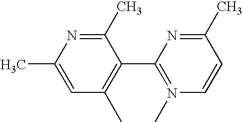 | 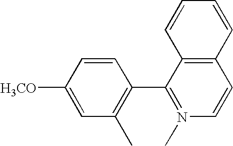 | 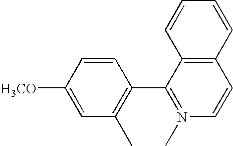 |

TABLE 6

| | CENTRAL | | | |
|---|---|---|---|---|
| No. | METAL | L₁ | L₂ | L₃ |
| 36 | Pt | 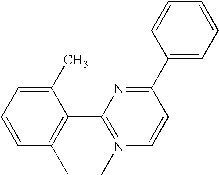 | 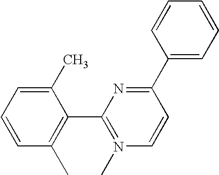 | — |
| 37 | Pt | 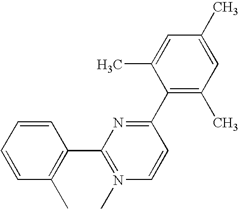 | 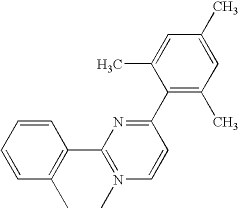 | — |
| 38 | Pt | 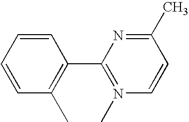 | 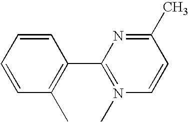 | — |
| 39 | Pt | 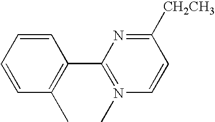 | 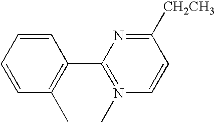 | — |
| 40 | Pt | 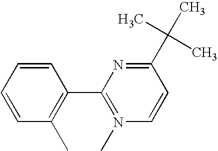 | 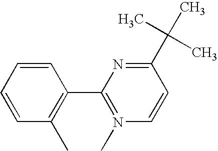 | — |
| 41 | Pt | 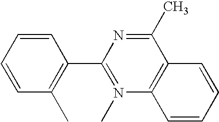 | 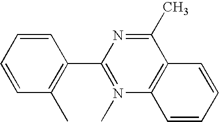 | — |
| 42 | Pt | 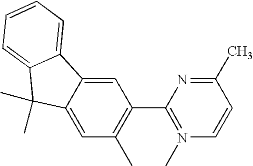 | 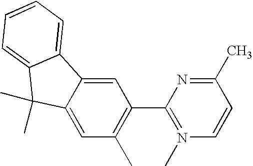 | — |

TABLE 7

| | CENTRAL | | | |
|---|---|---|---|---|
| No. | METAL | L₁ | L₂ | L₃ |
| 43 | Pt | 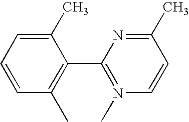 | 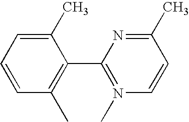 | — |
| 44 | Pt | 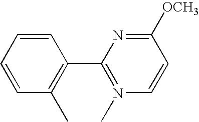 | 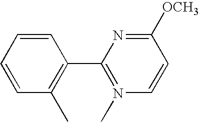 | — |
| 45 | Pt | 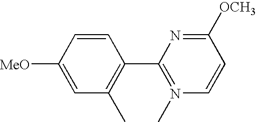 | 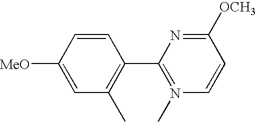 | — |

TABLE 8

| | CENTRAL | | | |
|---|---|---|---|---|
| No. | METAL | L₁ | L₂ | L₃ |
| 50 | Au | 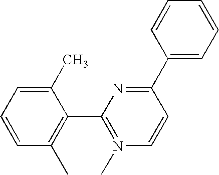 | 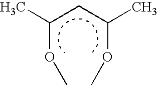 | — |
| 51 | Au | 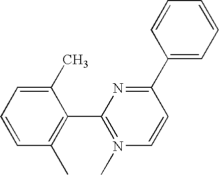 | 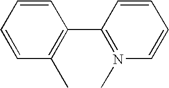 | — |
| 52 | Au | 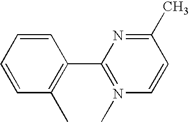 | 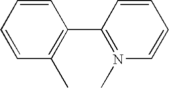 | — |

The organic light-emitting element in accordance with the present invention will be described below in greater detail. The organic light-emitting element in accordance with the present invention is composed of an anode, a cathode and a layer of an organic compound sandwiched between the anode and the cathode.

The organic light-emitting element in accordance with the present invention will be described below with reference to the appended drawings. The following reference numerals are used in the figures: 1—a substrate, 2—an anode, 3—a light-emitting layer, 4—a cathode, 5—a hole transport layer, 6—an electron transport layer, 7—a hole injection layer, 8—a hole/exciton blocking layer, and 10, 20, 30, 40, 50—respective organic light-emitting elements.

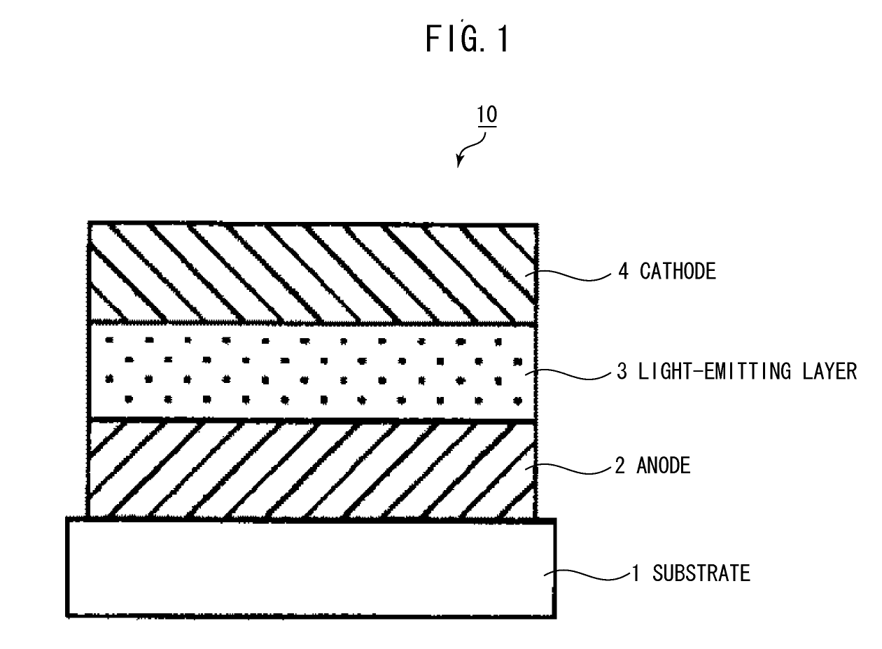

FIG. 1 is a cross-sectional view illustrating a first embodiment of the organic light-emitting element in accordance with the present invention. In the organic light-emitting element 10 in FIG. 1, the anode 2, light-emitting layer 3, and cathode 4 are successively provided on a substrate 1. The organic light-emitting element 10 shown in FIG. 1 is useful when the light-emitting layer 3 is composed of an organic compound combining hole transport ability, electron transport ability, and light emission ability. Further, the organic light-emitting element is also useful when the light-emitting layer is obtained by mixing organic compounds each having one characteristic from among the hole transport ability, electron transport ability, and light emission ability.

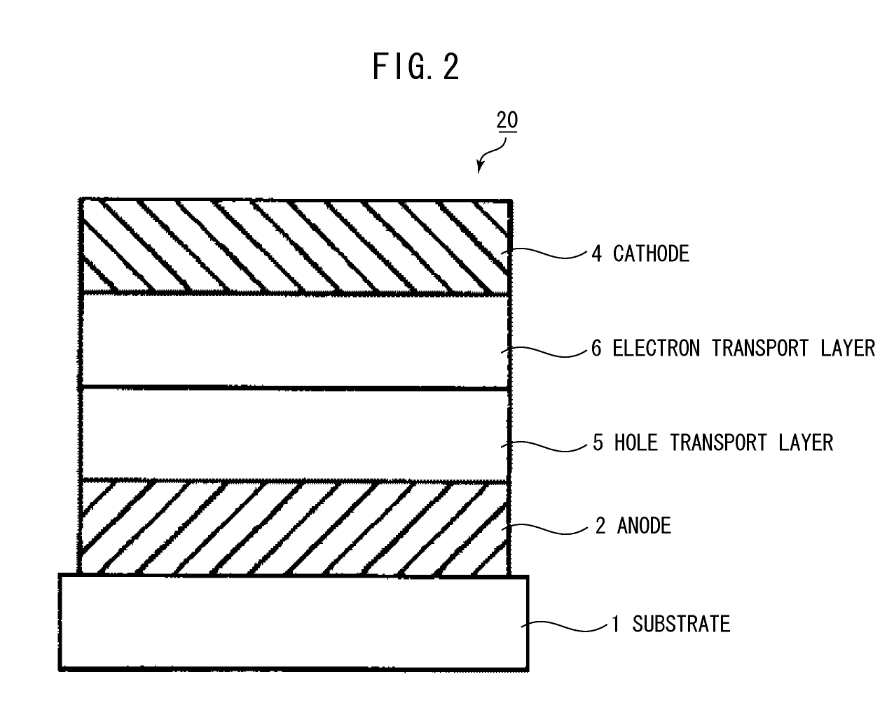

FIG. 2 is a cross-sectional view illustrating a second embodiment of the organic light-emitting element in accordance with the present invention. In an organic light-emitting element 20 shown in FIG. 2, an anode 2, a hole transport layer 5, an electron transport layer 6, and a cathode 4 are successively provided on a substrate 1. The organic light-emitting element 20 shown in FIG. 2 is useful when a light-emitting organic compound having any of hole transport ability and electron transport ability is used in combination with an organic compound having only the electron transport ability or only the hole transport ability. Further, in the organic light-emitting element 20 shown in FIG. 2, the hole transport layer 5 or electron transport layer 6 also serves as a light-emitting layer.

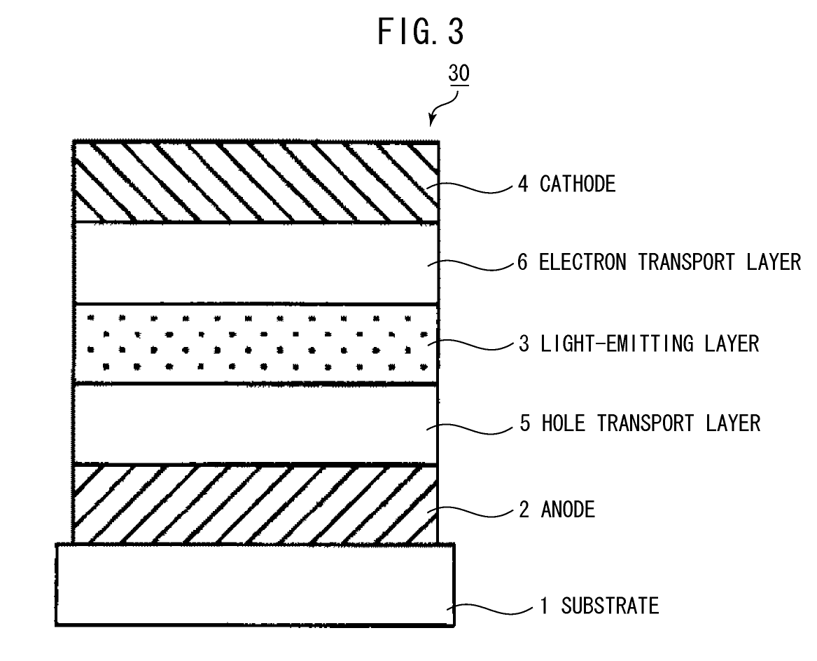

FIG. 3 is a cross-sectional view illustrating a third embodiment of the organic light-emitting element in accordance with the present invention. An organic light-emitting element 30 shown in FIG. 3 has a configuration of the organic light-emitting element 20 shown in FIG. 2 in which a light-emitting layer 3 is provided between a hole transport layer 5 and an electron transport layer 6. In this organic light-emitting element 30, the carrier transport function and the light emission function are separated, and organic compounds having respective characteristics from among the hole transport ability, electron transport ability, and light emission ability can be used in appropriate combinations. As a result, the degree of freedom in selecting suitable materials is increased and various compounds with different emission wavelengths can be used. Therefore, the variety of emission hues is increased. Further, it is also possible to confine effectively the carriers or excitons to the central light-emitting layer 3, thereby increasing the emission efficiency of the organic light-emitting element 30.

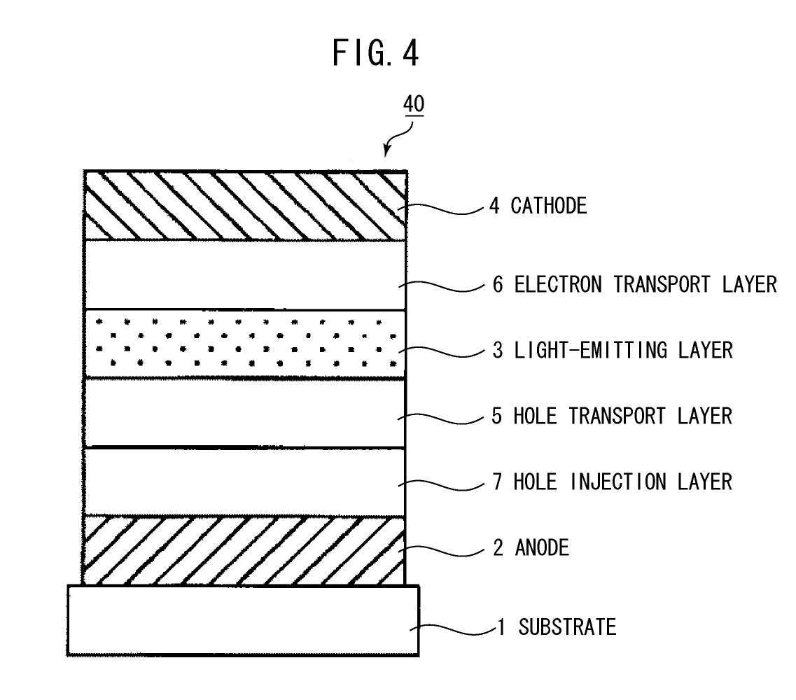

FIG. 4 is a cross-sectional view illustrating a fourth embodiment of the organic light-emitting element in accordance with the present invention. An organic light-emitting element 40 shown in FIG. 4 has a configuration of the organic light-emitting element 30 shown in FIG. 3 in which a hole injection layer 7 is provided between an anode 2 and a hole transport layer 5. Because the hole injection layer 7 is provided in the organic light-emitting element 40 shown in FIG. 4, adhesion of the anode 2 and hole transport layer 5 and the hole injection ability are improved. Therefore, the voltage supplied is effectively reduced.

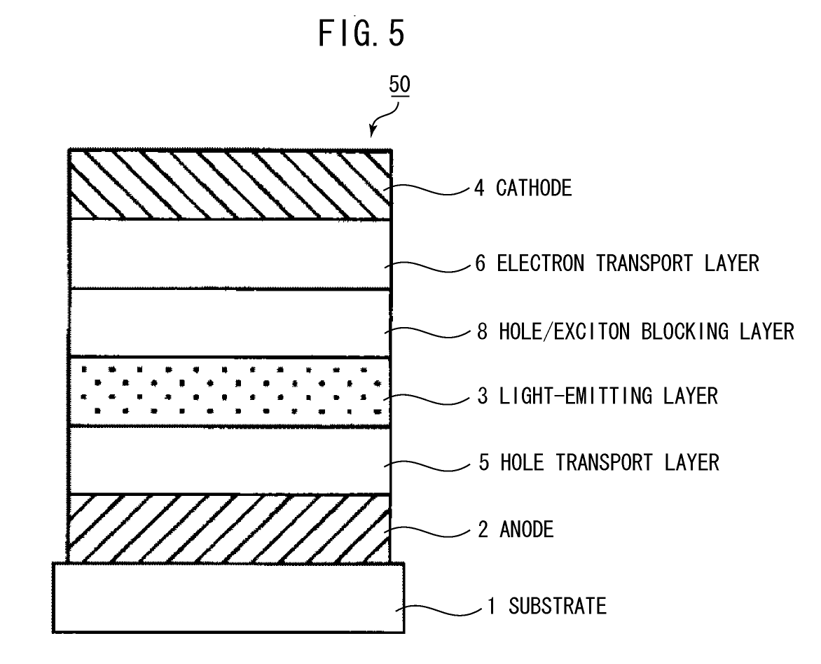

FIG. 5 is a cross-sectional view illustrating a fifth embodiment of the organic light-emitting element in accordance with the present invention. An organic light-emitting element 50 shown in FIG. 5 has a configuration of the organic light-emitting element shown in FIG. 3 in which a layer (hole/exciton blocking layer 8) that blocks the penetration of holes or excitons to the cathode 4 side is provided between a light-emitting layer 3 and an electron transport layer 6. By using an organic compound with a very high ionization potential for the hole/exciton blocking layer 8, it is possible to increase emission efficiency.

FIG. 1 to FIG. 5 show very basic element configurations, and the configuration of the organic light-emitting element in accordance with the present invention is not limited to these configurations. For example, a large variety of layered structures can be employed that have an insulating layer, an adhesive layer, or an interference layer on the interfaces of electrodes and organic layer and in which a hole transport layer is composed of two layers with different ionization potentials.

In the organic light-emitting element in accordance with the present invention, at least one kind of the organometallic complex in accordance with the present invention is contained in the layer composed of an organic compound. Here, specific examples of the layer composed of an organic compound include the light-emitting layer 3, hole transport layer 5, electron transport layer 6, hole injection layer 7, and hole/exciton blocking layer 8 shown in FIG. 1 to FIG. 5. In particular, the organometallic complex in accordance with the present invention can be used as a material constituting the hole transport layer 5, electron transport layer 6, and light-emitting layer 3. As a result, emission efficiency of the element is increased and service life thereof is extended.

The organometallic complex in accordance with the present invention is preferably used as a material constituting the light-emitting layer 3. Where the organometallic complex in accordance with the present invention is used as a material constituting the light-emitting layer, color purity, light emission efficiency, and service life of the element can be improved when the organometallic complex in accordance with the present invention is used in a variety of modes.

Thus, the organometallic complex in accordance with the present invention can be used as a constituent material of an organic light-emitting element and can be employed in any of the embodiments illustrated by FIG. 1 to FIG. 5.

The organometallic complex in accordance with the present invention can be used individually as a material constituting the light-emitting layer 3, or in combination with a guest as a dopant or a host of other fluorescent material and phosphorescent material. By using the organometallic complex in accordance with the present invention in combination with the guest or host, it is possible to improve the color purity, light emission efficiency, and service life of the element.

Specific examples of guests include triarylamine derivatives, condensation cyclic aromatic compounds (for example, naphthalene derivatives, phenanthrene derivatives, fluorene derivatives, pyrene derivatives, tetracene derivatives, coronene derivatives, chrysene derivatives, perylene derivatives, 9,10-diphenylanthracene derivatives, and rubrene), quinacridone derivatives, acridone derivatives, coumarine derivatives, pyrane derivatives, Nile Red, pyrazine derivatives, benzimidazole derivatives, benzothiazole derivatives, benzoxazole derivatives, stilbene derivatives, organometallic complexes (for example, organoaluminum complexes such as tris(8-quinolinolato)aluminum, and organoberyllium complexes, organoiridium complexes, and organoplatinum complexes), and also high-molecular derivatives such as poly(phenylenevinylene) derivatives, poly(fluorene) derivatives, poly(phenylene) derivatives, poly(thienylenevinylene) derivatives, and poly(acetylene) derivatives.

When the organometallic complex in accordance with the present invention is used in combination with a guest, the content ratio of the organometallic complex in accordance with the present invention is 0.1 wt. % to 40 wt. % based on the entire weight of the light-emitting layer.

Specific examples of hosts include triarylamine derivatives, phenylene derivatives, condensation cyclic aromatic compounds (for example, naphthalene derivatives, phenanthrene derivatives, fluorene derivatives, pyrene derivatives, tetracene derivatives, coronene derivatives, chrysene derivatives, perylene derivatives, 9,10-diphenylanthracene derivatives, and rubrene), quinacridone derivatives, acridone derivatives, coumarine derivatives, pyrane derivatives, Nile Red, pyrazine derivatives, benzimidazole derivatives, benzothiazole derivatives, benzoxazole derivatives, stilbene derivatives, organometallic complexes (for example, organoaluminum complexes such as tris(8-quinolinolato)aluminum, and organoberyllium complexes, organoiridium complexes, and organoplatinum complexes), and also high-molecular derivatives such as poly(phenylenevinylene) derivatives, poly(fluorene) derivatives, poly(phenylene) derivatives, poly(thienylenevinylene) derivatives, and poly(acetylene) derivatives.

When the organometallic complex in accordance with the present invention is used in combination with a host, the content ratio of the organometallic complex in accordance with the present invention is 0.1 wt. % to 40 wt. % based on the entire weight of the light-emitting layer.

Thus, in the organic light-emitting element in accordance with the present invention, the organometallic complex in accordance with the present invention is used, in particular, as a constituent material of the light-emitting layer. In addition to the organometallic complex in accordance with the present invention, if necessary, the organic light-emitting element in accordance with the present invention can also use heretofore known low-molecular or polymeric hole-transporting compounds, light-emitting compounds, and electron-transporting compounds.

Specific examples of hole-transporting compounds include triarylamine derivatives, aryldiamine derivatives, phthalocyanine derivatives, porphyrin derivatives, poly(vinylcarbazole), poly(silylene), poly(thiophene), and other conductive polymers.

Specific examples of light-emitting compounds that can be used in addition to the organometallic complex in accordance with the present invention include triarylamine derivatives, condensation cyclic aromatic compounds (for example, naphthalene derivatives, phenanthrene derivatives, fluorene derivatives, pyrene derivatives, tetracene derivatives, coronene derivatives, chrysene derivatives, perylene derivatives, 9,10-diphenylanthracene derivatives, and rubrene), quinacridone derivatives, acridone derivatives, coumarine derivatives, pyrane derivatives, Nile Red, pyrazine derivatives, benzimidazole derivatives, benzothiazole derivatives, benzoxazole derivatives, stilbene derivatives, organometallic complexes (for example, organoaluminum complexes such as tris(8-quinolinolato)aluminum, and organoberyllium complexes), and also high-molecular derivatives such as poly(phenylenevinylene) derivatives, poly(fluorene) derivatives, poly(phenylene) derivatives, poly(thienylenevinylene) derivatives, and poly(acetylene) derivatives.

Specific examples of electron transporting compounds include condensation cyclic aromatic compounds (for example, naphthalene derivatives, phenanthrene derivatives, fluorene derivatives, pyrene derivatives, tetracene derivatives, coronene derivatives, chrysene derivatives, perylene derivatives, 9,10-diphenylanthracene derivatives, and rubrene), oxadiazole derivatives, oxazole derivatives, thiazole derivatives, thiadiazole derivatives, pyrazine derivatives, triazole derivatives, triazine derivatives, perylene derivatives, quinoline derivatives, quinoxaline derivatives, fluorenone derivatives, anthrone derivatives, phenanethroline derivatives, and organometallic complexes.

Specific examples of materials constituting the cathode include individual metals such as lithium, sodium, potassium, calcium, magnesium, aluminum, indium, ruthenium, titanium, manganese, yttrium, silver, lead, tin, and chromium. Alloys in which these metals are combined may be also used. For example, lithium-indium, sodium-potassium, magnesium-silver, aluminum-lithium, aluminum-magnesium, and magnesium-indium alloys can be used. Metal oxides such as indium tin oxide (ITO) can be also used. These electrode substances may be used alone or in combination of a plurality thereof. The cathode may have a monolayer structure or a multilayer structure.

Specific examples of suitable materials constituting the anode include individual metals such as gold, platinum, silver, copper, nickel, palladium, cobalt, selenium, vanadium and tungsten, alloys thereof, or metal oxides such as tin oxide, zinc oxide, indium oxide, indium tin oxide (ITO), and indium zinc oxide. Further, conductive polymers such as polyaniline, polypyrrole, polythiophene, and polyphenylenesulfide can be also used. These electrode substances may be used alone or in combination of a plurality thereof. The anode may have a monolayer structure or a multilayer structure.

The substrate used in the organic light-emitting element in accordance with the present invention is not particularly limited, and an opaque substrate such as a metallic substrate or a ceramic substrate, or a transparent substrate such as glass, quartz, or a plastic sheet can be used.

Color light emission can be controlled by using a color filter film, a fluorescent color conversion filter film, a dielectric reflective film, or the like on the substrate. Further, the device can be produced by connecting to a thin-film transistor (TFT) produced on the substrate.

Further, the light can be taken out from the element in a bottom emission configuration (a configuration in which light is taken out from the substrate side) and a top emission configuration (a configuration in which light is taken out from the side opposite to the substrate side).

The organic light-emitting element in accordance with the present invention can be produced by a vacuum vapor deposition method, a solution coating method, a transfer method using a laser or the like, and a spraying method. In particular, where the organic layer comprising the organometallic complex in accordance with the present invention is formed by a vacuum vapor deposition method or a solution coating method, crystallization hardly occurs and the layer excels in long-term stability.

### EXAMPLES

The present invention will be specifically described below with reference to the Examples, but the present invention is not limited to thereto.

### Example 1

### Synthesis of Example Compound 17

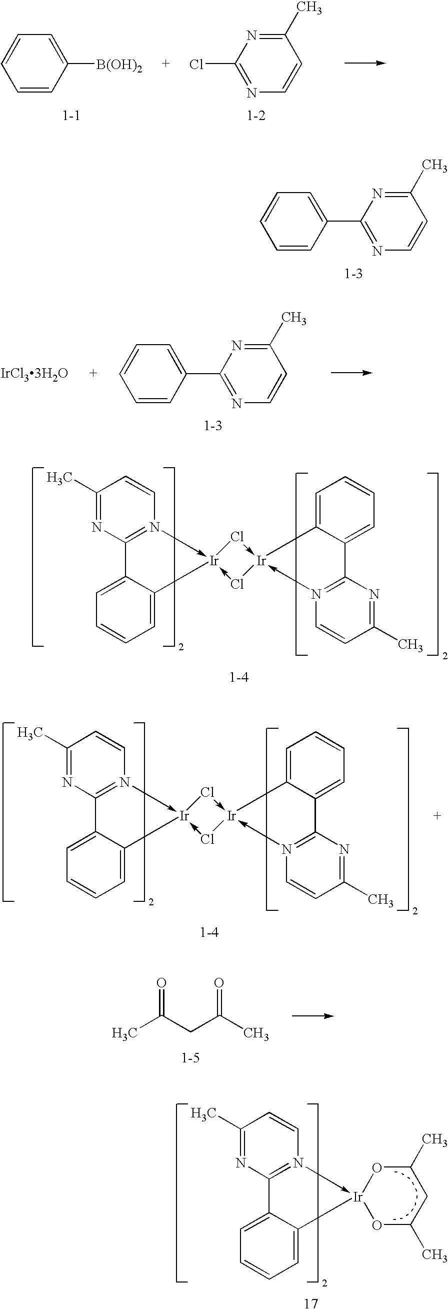

(1) The following reagents and solvents were charged into an eggplant type flask with a capacity of 300 mL.
Compound 1-1: 7.1 g (58 mmol).
Compound 1-2: 5.0 g (39 mmol).
Tetrakistriphenylphosphine palladium: 3.46 g (2.99 mmol)
2M aqueous solution of sodium carbonate: 50 mL.
Ethanol: 20 mL.
Toluene: 50 mL.

The reaction liquid was stirred for 6 h under heating and refluxing under a nitrogen gas flow. After the reaction, the reaction solution was cooled to room temperature and separated by adding 50 mL of toluene. An organic layer was then isolated, and the organic layer was then concentrated under reduced pressure. The concentrated substance was purified by silica gel column chromatography (developing solvent: toluene), thereby obtaining 6.22 g of Compound 1-3 (yield 82%).

(2) The following reagents and solvents were charged into a three-neck flask with a capacity of 100 mL.
Iridium (III) chloride trihydrate: 2.67 g (7.1 mmol).
Compound 1-3: 3.00 g (17.75 mmol).
Ethoxyethanol: 30 mL.
Water 10 mL.

The reaction liquid was then stirred for 30 min at room temperature under a nitrogen flow and then stirred for 7 h under heating and refluxing. Upon completion of the reaction, the reaction solution was cooled to room temperature and the precipitated sediment was filtered out and washed successively with water and ethanol. The sediment was then vacuum dried at room temperature to obtain 5.54 g (yield 83%) of Compound 1-4 in the form of a yellow powder.

(3) The below described reagents and solvents were charged into a three-neck flask with a capacity of 100 mL.
Ethoxyethanol: 100 mL.
Compound 1-4: 4.2 g (3.62 mmol).
Acetylacetone (Compound 1-5): 0.90 g (9.06 mmol).
Sodium carbonate: 8.0 g.

The reaction liquid was then stirred for 30 min at room temperature under a nitrogen flow and then stirred for 7 h under refluxing. Upon completion of the reaction, the reaction solution was ice cooled and the precipitated sediment was filtered out and washed with water. The sediment was then washed with ethanol, and dissolved in chloroform, followed by filtration of impurities. The filtrate was then concentrated under vacuum and recrystallized in chloroform-methanol, thereby producing 1.88 g (yield 82%) of Example Compound No. 17 in the form of a yellow powder. The M⁺ of the compound was confirmed by MALDI-TOF MS to be 659.7.

### Example 2

### Synthesis of Example Compound No. 3

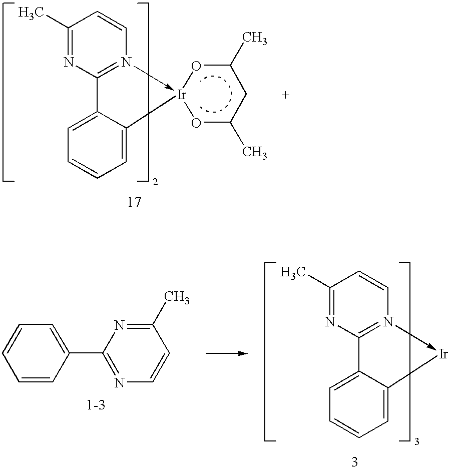

The following reagents and solvent were charged into a three-neck flask with a capacity of 100 mL.
Compound 1-3: 1.2 g (7.11 mmol).
Example Compound No. 17: 1.5 g (2.37 mmol).
Glycerol: 30 mL.

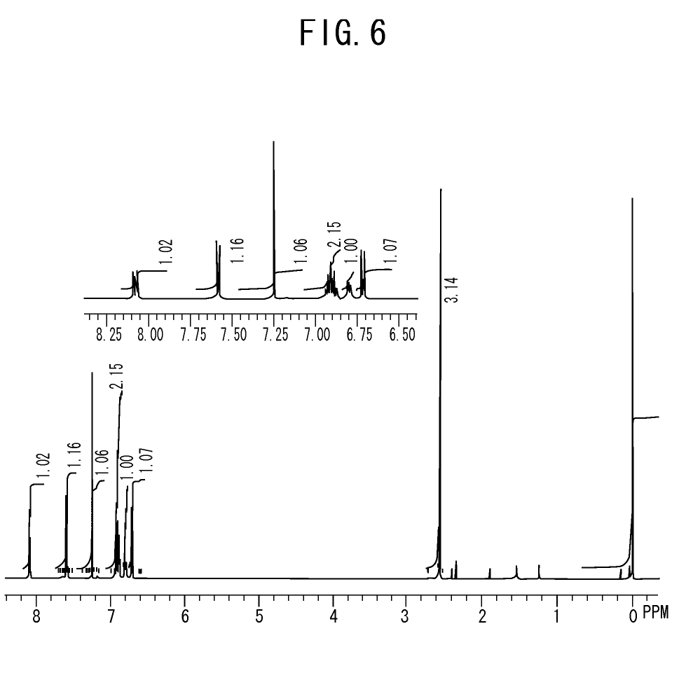

The reaction solution was then stirred for 8 h under heating at a temperature close to 180° C. under a nitrogen flow. Upon completion of the reaction, the reaction solution was cooled to room temperature. The reaction solution was then poured into 170 mL of 1N hydrochloric acid, and the precipitated sediment was filtered out, washed with water and vacuum dried for 5 h at 100° C. The sediment was purified by silica gel column chromatography using chloroform as a developing solvent to obtain 0.18 g (yield 11%) of Example Compound No. 3 in the form of a yellow powder. The M⁺ of the compound was confirmed by MALDI-TOF MS to be 700.2. A spectrum shown in FIG. 6 was obtained by conducting ¹H-NMR measurements, thereby confirming the structure of Example Compound No. 3.

¹H-NMR (CDCl₃, 400 MHz), SIGMA (ppm): 8.08 (d, 3H), 7.55 (d, 3H), 6.94-6.87 (m, 6H), 6.75 (d, 3H), 6.72 (d, 3H), 2.57 (s, 9H).

### Example 3

An organic light-emitting element having a structure shown in FIG. 3 was produced by the following method.

Indium tin oxide (ITO) was coated by a sputtering method on a glass substrate (substrate 1) to produce an anode 2. In this case, the film thickness of the anode 2 was 120 nm. The substrate on which the ITO was thus produced was successively ultrasonically washed in acetone and isopropyl alcohol (IPA) and then washed in boiling IPA and dried. Then, UV/ozone washing was performed. The substrate treated in the above-described manner was used as a transparent conductive support substrate.

A chloroform solution with a concentration of Compound 2-1 of 0.1 wt. % was then prepared using Compound 2-1 shown below as a hole transport material.

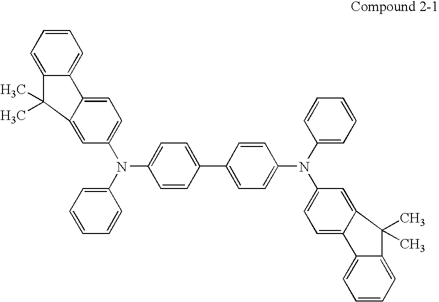

The solution was dropwise added onto the ITO electrode, and a thin film serving as a hole transport layer 5 was then formed by spin coating, first for 10 sec at a revolution speed of 500 RPM and then for 1 min at 1000 RPM. The solvent contained in the thin film was then completely removed by drying for 10 min at 80° C. in a vacuum oven. The thickness of the hole transport layer 5 thus formed was 15 nm.

Example Compound No. 3 serving as the first compound and Compound 2-2 described below that served as the second compound were then vapor co-deposited at a weight concentration ratio of 10:90 on the hole transport layer 5 to provide a light-emitting layer 3. The thickness of the light-emitting layer 3 in this case was 40 nm, the degree of vacuum during vapor deposition was 1.0×10⁻⁴ Pa, and the deposition rate was 0.2 nm/sec to 0.3 nm/sec.

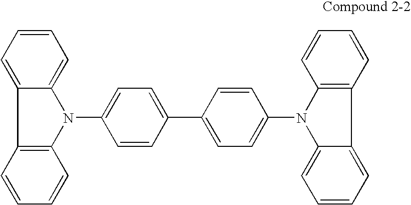

An electron transport layer 6 was then formed by producing a film of 2,9-[2-(9,9′-dimethylfluorenyl]-1,10-phenanthroline by vacuum vapor deposition on the light-emitting layer 3. The thickness of the electron transport layer 6 in this case was 30 nm, the degree of vacuum during vapor deposition was 1.0×10⁻⁴ Pa, and the deposition rate was 0.2 nm/sec to 0.3 nm/sec.

A thin film of aluminum-lithium (AlLi) was then formed by vacuum vapor deposition on the aforementioned electron transport layer 6. The thickness of the aluminum-lithium layer in this case was 0.5 nm, the degree of vacuum during vapor deposition was 1.0×10⁻⁴ Pa, and the deposition rate was 0.05 nm/sec.

An aluminum film was then provided by vacuum vapor deposition on the aforementioned aluminum-lithium film. The thickness of the aluminum film in this case was 150 nm, the degree of vacuum during vapor deposition was 1.0×10⁻⁴ Pa, and the deposition rate was 1.0 nm/sec to 1.2 nm/sec. The aluminum-lithium film and aluminum film functioned as an electron injection electrode (cathode 4).

A protective glass plate was then covered in a dry air atmosphere and sealed with an acrylic resin adhesive to prevent the element from deterioration caused by adsorption of moisture. An organic light-emitting element was thus produced.

When a voltage of 4 V was applied to the obtained organic light-emitting element by taking the ITO electrode (anode 2) as a positive electrode and an Al electrode (cathode 4) as a negative electrode, intensive green emission was observed.

The organometallic complex in accordance with the present invention has been developed based on the design guidelines mentioned in the section of the description relating to means for attaining the object of the present invention, and this organometallic complex is a material having excellent emission characteristics. Therefore, the organometallic complex in accordance with the present invention is useful as a constituent material for an organic light-emitting element.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-208038, filed Aug. 9, 2007, which is hereby incorporated by reference herein in its entirety.

What is claimed is:

1. An organometallic complex represented by General Formula [I] below: 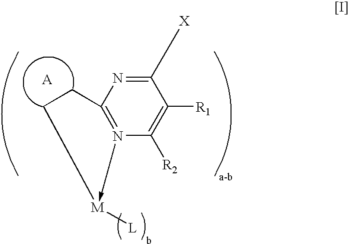
wherein in Formula [I], M is iridium, platinum, or gold, A is a substituted or unsubstituted aryl group, X is a substituted or unsubstituted alkyl group, a substituted or unsubstituted aralkyl group, a substituted or unsubstituted alkoxy group, a substituted or unsubstituted aryloxy group, a substituted or unsubstituted aryl group, a substituted or unsubstituted heterocyclic group, or a cyano group. R₁ and R₂ are the same or different, and are each a hydrogen atom, a substituted or unsubstituted alkyl group, a substituted or unsubstituted aralkyl group, a substituted or unsubstituted alkoxy group, a substituted or unsubstituted aryloxy group, a substituted or unsubstituted aryl group, a substituted or unsubstituted heterocyclic group, an amino group, a cyano group, a halogen atom, or, R₁ and R₂ may be bonded to each other to form a ring, L is an optionally substituted monoanionic bidentate ligand, a is integer of 1 to 3, b is integer of 0 to 2, and when b is 2, each L may be the same or different.

2. The organometallic complex according to claim 1, wherein M is iridium or platinum.

3. The organometallic complex according to claim 1, wherein A is a substituted or unsubstituted phenyl group.

4. The organometallic complex according to claim 1, wherein X is a substituted or unsubstituted alkyl group.

5. The organometallic complex according to claim 1, wherein b is 0.

6. An organic light-emitting element comprising:
an anode and a cathode; and
a layer comprising an organic compound sandwiched between the anode and the cathode, wherein at least one kind of the organometallic complex according to claim 1 is contained in the layer comprising the organic compound.

7. The organic light-emitting element according to claim 6, wherein the organometallic complex is contained in a light-emitting layer.
